(19) United States
(12) Patent Application Publication
(10) Pub. No.: US 2017/0170097 A1
(43) Pub. Date: Jun. 15, 2017

(54) POWER UNIT COOLING MECHANISM

(71) Applicant: FUJI ELECTRIC CO., LTD., Kawasaki-shi (JP)

(72) Inventors: Ryohei MAKINO, Hachioji (JP); Motoyoshi KUBOUCHI, Matsumoto (JP)

(73) Assignee: FUJI ELECTRIC CO., LTD., Kawasaki-shi (JP)

(21) Appl. No.: 15/340,898

(22) Filed: Nov. 1, 2016

(30) Foreign Application Priority Data
Dec. 14, 2015 (JP) 2015-243555

(51) Int. Cl. H01L 23/467; H01L 23/367

(52) U.S. Cl. CPC H01L 23/467; H01L 23/3672; H01L 29/1608

(57) ABSTRACT

A power unit cooling body includes a base part on which a first power semiconductor module and a second power semiconductor module are mounted. A cooling body is mounted on a side of the base part opposite the first power semiconductor module and the second power semiconductor module. A height of a fin of the cooling body is configured to be made shorter on the windward side than on the leeward side.

### CROSS REFERENCE TO RELATED APPLICATION

This application is based upon and claims the benefit of priority of the prior Japanese patent application NO. JP2015-243555, filed on Dec. 14, 2015, the entire contents of which are incorporated herein by reference.

### TECHNICAL FIELD

The present invention relates to a power unit cooling mechanism that is provided with a power semiconductor module and forcibly cooled by an air blast from a blowing source, wherein the power unit constitutes a power electronics device that performs a power conversion using a power semiconductor device.

### BACKGROUND ART

As is well known, generally, in a power unit that constitutes a power electronics device that performs a power conversion using a power semiconductor device, a power semiconductor module is cooled by mounting it on a cooling body because an amount of heat generated by the power semiconductor module is large.

As a method for cooling a cooling body, there exist air cooling and liquid cooling such as water cooling, and as one of the cooling methods that is classified as air cooling, there exists a natural air cooling that does not particularly blow air to a cooling body and a forced air cooling that blows air to a cooling body from a blowing source such as a fan or a blower.

A cooling body for air cooling is constituted of a base part that is a flat area that provides a plane on which a power semiconductor module is mounted, and a fin part constituted of a plurality of rectangular cooling plates provided on a surface of the base part that is opposite to another surface on which the power semiconductor module is mounted, such that the cooling plates extend in a direction opposite to the another surface on which the power semiconductor module is mounted.

Both parts are generally made of metal with a high thermal conductivity, and there exist, for example, a cooling body with a fin called an “extrusion-type” in which a base part and a fin part are integrally molded, and a cooling body with a fin called a “swage fin” in which a plurality of cooling plates that constitute fins are swaged and mounted on a base plate.

In general, a cooling body that includes a fin having a larger surface area has a higher cooling performance, so if the envelope volumes are identical, the cooling performance of a cooling body with a swage fin in which thin plate fins can easily be spaced narrowly can be enhanced more easily.

FIG. 1A is a schematic diagram of a configuration of a conventional power unit cooling mechanism 100. In FIG. 1A, a first power semiconductor module 20 and a second power semiconductor module 30 are provided on a power unit cooling body 40, wherein the first power semiconductor module 20 is located on the windward side and the second power semiconductor module 30 is located on the leeward side, and the cooling body 40 is a forced air cooling type in which the cooling body 40 is cooled by an air blast from a blowing source 10.

Conventionally, the configuration is made such that a side shape of a fin 44 is rectangular when the fin 44 is viewed from a direction perpendicular to a wind direction.

Thus, in the conventional power unit cooling mechanism, there occurs a decrease in a wind speed and in the flow rate of wind on the leeward side due to a friction resistance caused between the fin 44 and air on the windward side, which results in decreasing the cooling performance for the power semiconductor modules 20 and 30.

When an isothermal chart in the power unit cooling mechanism of FIG. 1A is created, cooling is excessive at the lower part of a fin on the windward side, as represented by FIG. 1B. The portion in which cooling is excessive makes a small contribution to the whole cooling body, and causes a friction against a wind, which results in decreasing a wind speed.

The isothermal chart of FIG. 1B is an isothermal chart during an operation of the power unit, which is obtained by performing a thermal analysis on a cooling body that uses the rectangular cooling plate (fin) 44 of FIG. 1A on the assumption that the power unit is operating, or by actually operating the power unit to obtain an image of a heat distribution using thermography. In FIG. 1B, different thermal thresholds are represented by different line thicknesses. As shown in FIG. 1B, a first side 44a of the fin 44 closest to a blowing source 10 has a larger area having a cooler temperature (represented by the area under the thickest line) than a second side 44b of the fin 44 farthest from the blowing source 10.

FIG. 1B illustrates an example of an isothermal chart when the levels of a heat generation of the first and second semiconductor modules of FIG. 1A are similar.

It is obvious to a person skilled in the art that there occurs a more significant decrease in a wind speed on the leeward side when a swage fin in which the spacing between fins is made narrow is used, compared to when the above-described extrusion-type fin is used.

Further, Patent Document 1 described below discloses a heat sink that averages a distribution of a wind speed between fins, wherein the distribution of a wind speed is averaged by arranging a fin situated in an area that is not near a cooling fan such that the tip of the fin is positioned more downstream than the tip of another fin situated in an area that is near the cooling fan.

Conventionally, a plurality of power semiconductor modules may be arranged on one cooling body in a power unit that constitutes a power electronics device that performs a power conversion using a power semiconductor device.

Specifically, in recent years, there has been an increasing need for downsizing, simplification, and cost reduction of devices, and it is often the case that one cooling body is shared not only by a plurality of power semiconductor modules included in one circuit unit but also by a plurality of power semiconductor modules that belong to a plurality of circuit units.

A device can be made smaller due to lower loss and higher frequency if a power semiconductor module is used that particularly uses a wide bandgap semiconductor such as SiC (silicon carbide) and GaN (gallium nitride), so power semiconductor modules or devices for which power semiconductor modules are used have been actively commercialized or developed in recent years.

However, there has been a problem in which switching is performed at high speed in a device made of SiC (silicon carbide) or GaN (gallium nitride), so a surge voltage becomes high when a parasitic inductance of wiring between modules is large, which may result in exceeding the voltage resistance of the device and destroying it.

Thus, wiring needs to be shortened in order to make the parasitic inductance smaller, which leads to a high requirement for providing a plurality of power semiconductor modules in one cooling body.

In addition, the plurality of power semiconductor modules are arranged on the windward side and on the leeward side in relation to each other when a forced air cooling is performed by an air blast from a blowing source such as a fan or a blower.

In this case, there has been a problem in which there occurs a decrease in a wind speed and in the flow rate of wind on the leeward side due to a friction resistance caused between a fin and air on the windward side, which results in decreasing the cooling performance.

There has been a problem in which, if the cooling body is made larger in order to compensate for the above-described weakness, not only is the device made larger and heavier, but the cooling performance of the cooling body is not as enhanced as expected for its large size.

Patent Document 1: Japanese Laid-open Patent Publication No. 2008-140802

### DISCLOSURE OF INVENTION

An object of the present invention is to provide a power unit cooling mechanism that makes it possible to enhance a cooling performance of a power unit cooling body without making the cooling body larger or heavier.

In order to achieve the object described above, an aspect of the present invention provides a power unit cooling mechanism that includes a plurality of cooling plates cooled by a cooling wind on one surface of a base part, wherein a plurality of power semiconductor modules are mounted on another surface of the base part that is opposite to the one surface, the power semiconductor modules being arranged on the windward side and on the leeward side in relation to each other, wherein the cooling plate is formed such that the shape of a side situated opposite to the base part is along the outline of an isotherm during an operation of the power unit when the cooling plate is rectangular.

Another aspect of the present invention provides the power unit cooling mechanism in which the cooling plate is constituted of a swage fin.

Yet another aspect of the present invention provides the power unit cooling mechanism in which the power semiconductor module is configured to include at least a wide bandgap semiconductor device.

In the above-described case, the wide bandgap semiconductor device is preferably constituted of an SiC (silicon carbide) or GaN (gallium nitride) element.

According to the embodiments of the present invention, it is possible to enhance the cooling performance of a power unit cooling body that is provided with a plurality of power semiconductor modules without making the cooling body larger or heavier, which results in being able to realize a small and light power electronics device with a high density of power.

### BRIEF DESCRIPTION OF DRAWINGS

FIG. 1A is a schematic diagram of a configuration of a conventional power unit cooling mechanism and FIG. 1B is an isothermal chart of the cooling fin of the cooling mechanism;

FIG. 2 is a schematic diagram of a configuration of a power unit cooling mechanism according to an embodiment of the present invention;

FIG. 3 is a variation (part 1) of the power unit cooling mechanism according to the embodiment of the present invention; and

FIG. 4 is a variation (part 2) of the power unit cooling mechanism according to the embodiment of the present invention.

### DESCRIPTION OF EMBODIMENTS

Embodiments will now be described with reference to the drawings.

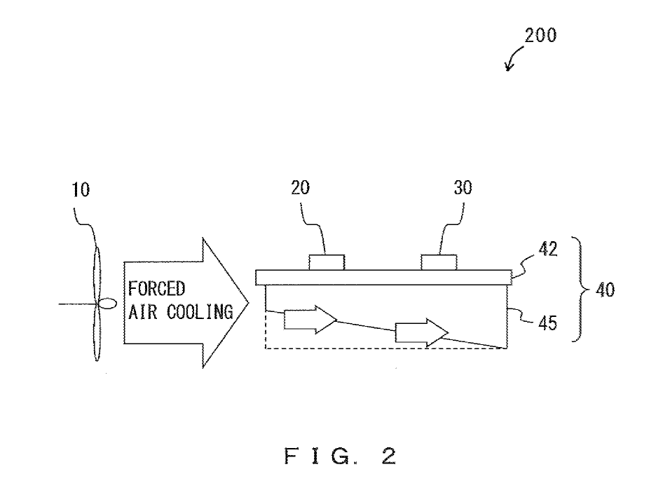

FIG. 2 is a schematic diagram of a configuration of a power unit cooling mechanism 200 according to an embodiment of the present invention.

The power unit cooling mechanism 200 of FIG. 2 is a power unit cooling mechanism 200 of a forced air cooling type in which a cooling body 40 is cooled by an air blast from a blowing source 10, and is provided with a first power semiconductor module 20 and a second power semiconductor module 30 on a base plate 42 that constitutes the cooling body 40, wherein the first power semiconductor module 20 is located on the windward side and the second power semiconductor module 30 is located on the leeward side. The length of a fin 45 mounted on the base plate 42 is made shorter on the windward side than on the leeward side.

In other words, as illustrated in FIG. 2, the basic power unit cooling mechanism 200 according to the embodiment of the present invention has a configuration in which the length of the fin 45 mounted on the base plate 42 is continuously and linearly made longer from the windward side to the leeward side so that the entirety of the side shape of the fin 45 is trapezoidal when the cooling body 40 is viewed from a direction perpendicular to a direction of a wind passage.

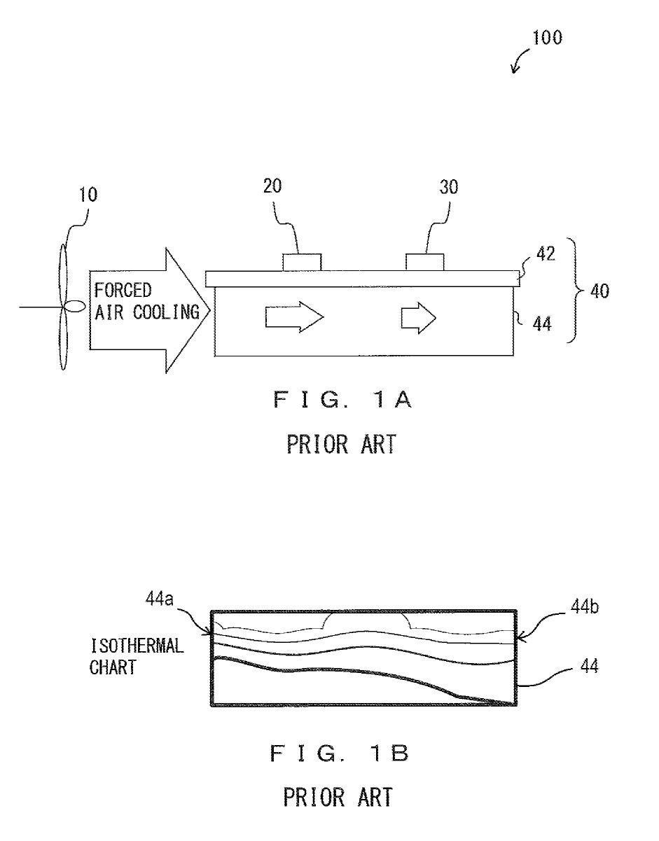

As described above, in the power unit cooling mechanism 200 according to the embodiment of the present invention of FIG. 2, a portion of the lower part of the fin 45 which is unnecessary for a cooling wind is cut continuously and linearly in a tapered shape from the windward side to the leeward side in the conventional power unit cooling mechanism 100 of FIG. 1A, so that the fin 45 has a shape in which an obstacle that causes a friction against a cooling wind is removed without detracting from the cooling effect of the whole cooling body.

This permits obtaining of the same speed of cooling wind on the leeward side as on the windward side, which results in preventing a decrease in the flow rate of cooling wind and in the cooling performance.

Further, if a portion of the fin 45 is cut continuously and linearly in a taper shape from the windward side to the leeward side, it is possible to make the fin lighter and to realize resource savings for the cut portion at the same time.

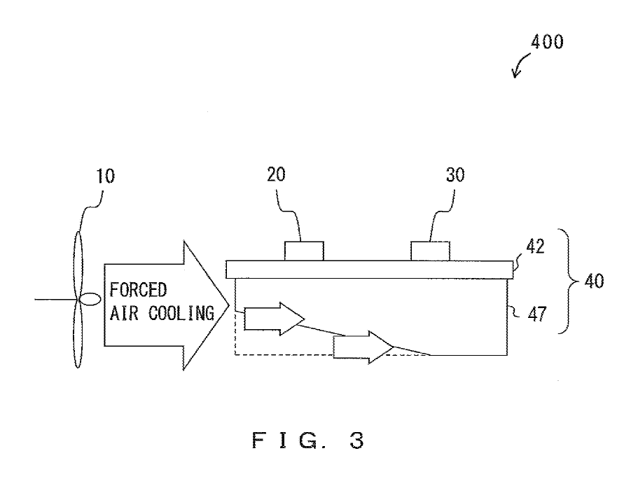

FIG. 3 is a variation of the power unit cooling mechanism 300 according to the embodiment of the present invention.

In the variation of the power unit cooling mechanism 300 according to the present invention illustrated in FIG. 3, the bottom part of the fin 46 has a portion parallel to the base plate (base part) 42 on the leeward side of a cooling wind, the bottom part being situated opposite to the base plate (base part) 42 of the fin 46.

This permits obtaining of the same speed of cooling wind on the leeward side as on the windward side, which results in preventing a decrease in the flow rate of cooling wind and in the cooling performance.

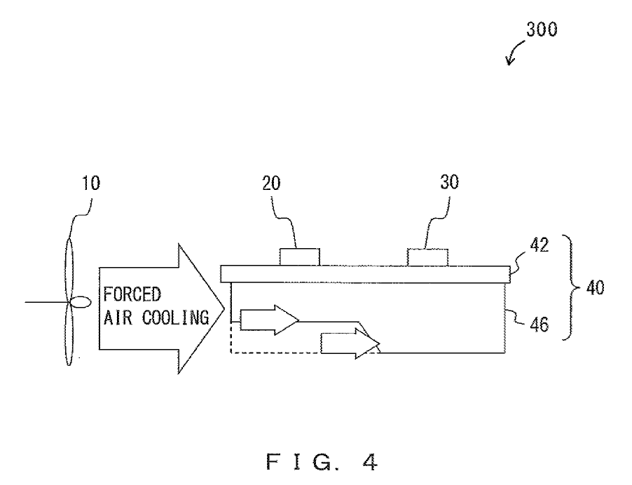

FIG. 4 is a variation of the power unit cooling mechanism 400 according to the embodiment of the present invention.

In the variation of the power unit cooling mechanism 400 according to the present invention illustrated in FIG. 4, a stair-like step is provided according to the arrangement of the power semiconductor modules 20 and 30 when the shape of the fin 47 is viewed from a direction perpendicular to a direction of a cooling wind passage. The stair-like step provided in the fin 47 may have a curved shape instead of a linear one.

This permits obtaining of the same speed of cooling wind on the leeward side as on the windward side, which results in preventing a decrease in the flow rate of cooling wind and in the cooling performance.

It has been experimentally confirmed that, in the case of the conventional cooling mechanism 100 of FIG. 1A in which the fin 44 is rectangle-shaped, there occurs a more significant decrease in a wind speed and in the flow rate of wind on the leeward side when a swage fin in which fins are spaced narrowly is used, compared to when an extrusion-type fin is used. However, it has been experimentally confirmed that there occurs no decrease in a wind speed and in the flow rate of wind on the leeward side when a swage fin is used in any one of the above-described power unit cooling mechanisms according to the embodiments of the present invention.

Thus, it is understood that a greater cooling effect will be obtained if the power unit cooling mechanisms according to the embodiment of the present invention are used.

Further, when a swage fin is used, it is possible to realize any one of the above-described examples just by changing the shapes of cooling plates that are to be swaged and mounted on the base part 42, so there does not occur any significant change in a process of assembling a cooling body itself and it is possible to obtain a greater flexibility in the shape of the cooling body.

Further, a device can be made smaller due to lower loss and higher frequency if a recent power semiconductor module is used that uses a wide bandgap semiconductor such as SiC (silicon carbide) and GaN (gallium nitride). On the other hand, switching is performed at high speed in such a device, so a surge voltage becomes high when a parasitic inductance of wiring between modules is large, which may result in exceeding the voltage resistance of the device and destroying it.

However, if one of the above-described power unit cooling mechanisms according to the embodiment of the present invention is used, it is possible to provide a plurality of power semiconductor modules in one cooling body with an arrangement in which the thermal density is higher, so that they are suitable as a cooling mechanism for a power electronics device that uses a power semiconductor module that uses a wide bandgap semiconductor.

The present embodiment relates to a power unit cooling mechanism of a forced air cooling type in which a cooling body is cooled by an air blast from a blowing source, but it is also applicable to a power unit cooling mechanism that is provided in a railroad vehicle and cooled by wind generated due to the vehicle traveling.

In other words, according to the embodiment of the present invention, it is possible to enhance the cooling performance of a power unit cooling body that is provided with a plurality of power semiconductor modules without making the cooling body larger or heavier, which results in being able to realize a small and light power electronics device with a high density of power.

### INDUSTRIAL APPLICABILITY

The technology of the present invention has only been described using a power unit cooling mechanism of a forced air cooling type in which a cooling body is cooled by an air blast from a blowing source, but it is also applicable to a power unit cooling mechanism that is provided in a railroad vehicle and cooled by wind generated due to the vehicle traveling.

What is claimed is:

1. A power unit cooling mechanism comprising:
a base part having at least two semiconductor modules mounted thereon; and
a plurality of cooling plates connected to a surface of the base part opposite a surface on which the at least two semiconductor modules are mounted, and configured to be cooled by a cooling wind on one surface of a base part,
wherein the power semiconductor modules are arranged in a direction of a flow of the cooling wind, wherein each of the plurality of cooling plates has a shape that corresponds to an isotherm pattern of a rectangular cooling plate during an operation of the power unit with the rectangular cooling plate.

2. The power unit cooling mechanism according to claim 1, wherein the cooling plate includes a swage fin.

3. The power unit cooling mechanism according to claim 1, wherein the power semiconductor module is configured to include at least a wide bandgap semiconductor device.

4. The power unit cooling mechanism according to claim 3, wherein the wide bandgap semiconductor device is constituted of an SiC (silicon carbide) or GaN (gallium nitride) element.

5. A power unit cooling mechanism, comprising:
a base part having at least two semiconductor modules mounted thereon;
at least one cooling fin connected to a surface of the base part opposite a surface on which the at least two semiconductor modules are mounted,
wherein the at least two semiconductor modules are arranged along a length-wise direction of the at least one cooling fin, and
wherein the at least one cooling fin has a first height at a first end that is lower than a second height at a second end opposite the first end.

6. The power cooling mechanism according to claim 5, wherein the at least one cooling fin has a trapezoidal shape.

7. The power cooling mechanism according to claim 5, wherein the at least one cooling fin is attached to the base plate on a third surface, and includes a fourth surface opposite the third surface, wherein the fourth surface is diagonal relative to the fourth surface.

8. The power cooling mechanism of claim 7, wherein the entire fourth surface is diagonal relative to the third surface.

9. The power cooling mechanism of claim 7, wherein a first portion of the fourth surface is parallel to the third surface, and a second portion of the fourth surface is diagonal to the third surface.

10. The power cooling mechanism of claim 9, wherein the fourth surface includes the first portion adjacent to the first end of the cooling fin, the second portion adjacent to the first portion, and a third portion parallel to the third surface and positioned between the second portion and the second end of the cooling fin.

11. The power cooling mechanism of claim 5, further comprising a blowing source configured to direct a cooling wind onto the first end of the cooling fin, such that the cooling wind flows from the first end of the cooling fin towards the second end of the cooling fin.
